(19) United States
(12) Patent Application Publication
(10) Pub. No.: US 2024/0405655 A1
(43) Pub. Date: Dec. 5, 2024

(54) ULTRA LOW NOISE, HIGH STABILITY, HIGH PRECISION VOLTAGE OR CURRENT SOURCE

(71) Applicant: ZEALOGICS TECHNOLOGIES PVT. LTD, Kochi (IN)

(72) Inventor: Gursaran Singh Bhumbra, Leicester (GB)

(21) Appl. No.: 18/678,981

(22) Filed: May 30, 2024

(30) Foreign Application Priority Data
May 31, 2023 (IN) 202341037646

(51) Int. Cl. H02M 1/00; H01J 37/24; H02M 1/44

(52) U.S. Cl. CPC H02M 1/0012; H01J 37/241; H02M 1/44

(57) ABSTRACT

Disclosed herein is a system and method to generate ultra low noise voltage and current, by using feedback of noise to nullify the original, inherent noise produced by the electronic hardware components. The system comprises: one or more Analog to Digital converters (ADCs) for high precision digital reading of DC and AC ripple values; a microcontroller to process the ADC output readings and generate a waveform; a digital to analog converter (DAC) to implement the subtraction generated from the microcontroller; a high voltage amplifier for amplifying the ripple-free subtracted waveform output generated from the DAC; a very low frequency (VLF) noise bandpass filter (BPF) to detect the noise and filter out the significant frequency components to obtain the low frequency noise as output; and power and reference section to provide necessary voltage levels and precision references for proper functioning of system.

### FIELD OF THE INVENTION

The present invention generally relates to systems and methods for reducing output noise generated by electronic hardware components. More specifically, the present invention relates to systems and methods for generating an ultra low noise, high stability, high precision voltage or current in imaging systems such as scanning electron microscopes.

### BACKGROUND

Noise shaping is a technique used in electronic hardware components and imaging systems to reduce the impact of noise and drift errors on the system's performance. It involves shaping the frequency spectrum of the noise in such a way that it is concentrated in frequency bands where it is less perceptible or can be filtered out more easily.

The importance of reducing noise and drift errors in electronic hardware components and imaging systems cannot be overstated. Noise can cause fluctuations in signals and introduce errors in measurements, which can degrade the performance of the system. Drift errors, on the other hand, can cause gradual changes in signal levels or offsets over time, which can also cause errors in measurements or image acquisition.

By using noise shaping, it is possible to minimize the impact of noise and drift errors on the system's performance. This is achieved by applying a controlled noise signal to the system's output signal that shifts the noise to higher frequencies, where it is less perceptible or can be filtered out more easily. This can result in improved signal-to-noise ratios and reduced errors in measurements or image acquisition.

In addition to reducing noise and drift errors, noise shaping can also improve the resolution and dynamic range of the system, making it more sensitive to small changes in signals or changes in the environment.

Existing prior art discloses a method for estimating switching mismatch error for reducing errors from the feedback DAC and utilizing the noise-shaping in a charge redistribution successive approximation register (SAR) analog-to-digital converter (ADC).

For example, U.S. Pat. No. 9,716,509 to Analog Devices Inc titled “Digital measurement of DAC switching mismatch error” relates to analog-to-digital converters (ADCs) which utilize a feedback digital-to-analog converter (DAC) for conversion, the final analog output can be affected or distorted by errors of the feedback DAC. A digital measurement technique can be implemented to determine switching mismatch error for the feedback DAC in a continuous-time delta-sigma modulator (CTDSM) or a continuous-time pipeline modulator. The obtained errors can be stored in a look-up table and fully corrected in the digital domain or analog domain.

A non-patent literature titled “An error-feedback noise-shaping SAR ADC in 90 nm CMOS” discloses a structure to utilize the noise-shaping in a charge redistribution successive approximation register (SAR) analog-to-digital converter (ADC). The proposed ADC is based on the error feedback structure and it does not require any extra capacitor compared to the main SAR ADC and by employing an operational transconductance amplifier (OTA), a first-order noise-shaping is provided.

Even though prior art attempt to propose techniques to implement noise shaping, some applications like scanning electron microscopes required ultra low noise voltages and currents, for their quality of image outputs. These conventional techniques for generating such voltages and current cannot go beyond a limit in reducing noise levels. Hence, there exists a necessity for a novel system that can solve the limitations faced by conventional systems.

The present invention proposes a system and method to reduce noise and drift errors in a generated voltage or current source of electronic hardware components.

### OBJECTIVES OF THE INVENTION

The primary objective of the present invention is to provide a system and method to generate ultra low noise, high stability, high precision voltage or current source and improve the quality of outputs in applications such as scanning electron microscopes, and other imaging systems.

Another objective of the present invention is to correct drift errors in a generated voltage or current source of the electronic hardware components in the system.

Yet another objective of the present invention is to produce voltage and current that is cleaner with low level of noise and drift than that is possible by the present state-of-art technologies.

Yet another objective of the present invention is to provide a dual feedback loop to eliminate both the static or DC error as well as the low frequency or flicker type noise.

Other objects and advantages of the present invention will be more apparent from the following description when read in conjunction with the accompanying figures, which are not intended to limit the scope of the invention.

### SUMMARY

To achieve the aforementioned objectives, the present invention discloses system and method to generate ultra low noise voltage and current, by using feedback signal via multiple ADC, processing and feeding it to oversampling DAC to nullify the original, inherent noise produced by the electronic hardware components in the system.

According to the present invention, the system to generate ultra low noise, high stability, high precision voltage or current source in electronic hardware components, comprises:
a. one or more Analog to Digital converters (ADCs) for high precision digital reading of DC and AC error values;
b. a microcontroller to process the ADC output readings and generate a waveform that when subtracted from the output will provide the steady, reduced error output;
c. a digital to analog converter (DAC) to implement the subtraction generated from the microcontroller;
d. a high voltage amplifier for amplifying the ripple-free subtracted waveform output generated from the DAC and generating the output according to user command;
e. a very low frequency (VLF) noise bandpass filter (BPF) to detect the noise and filter out the significant frequency components to obtain the low frequency noise as output; and
f. power and reference section to provide necessary voltage levels and precision references for the proper functioning of the system,
   wherein the noise output from the filter is applied as negative feedback to eliminate maximum noise using extended precision oversampling DAC codes to nullify the original, inherent noise produced by the electronic hardware components containing applications.

In accordance with the present invention, applications containing electronic hardware components include scanning electron microscopes and other imaging systems.

In accordance with the present invention, the method for generating ultra low noise, high stability, high precision voltage or current source in electronic hardware components, comprising:
a. detecting noise using a bandpass filter and measuring low frequency noise;
b. applying negative feedback of that noise to eliminate most of that noise using extended precision oversampling DAC codes to the existing codes used to set the output voltage and current; and
c. eliminating the low frequency noise and drift errors arising from the voltage reference source, amplifier, or DAC LSB errors.

According to present invention, the system and method reduce the output noise of a voltage or current source, to a level far below to what is achieved by the state of art technologies. This technology basically scans the output in two ways, 1. DC feedback, 2. AC feedback. The DC feedback is used to set up and maintain the output, according to the command given to the system by the user, whereas the AC feedback is used to sample the ripple, and by using a microcontroller and firmware combination, process the ripple, and nullify it at the output, by subtracting from the output. This subtraction is achieved by an over-sampled DAC that provides 24-bit effective resolution.

In accordance with present invention, the dual feedback loop is important to eliminate both the static or DC error as well as the low frequency or flicker type noise.

Advantageously, the system and method of present invention reduces noise and drift errors in a generated voltage or current source and improve the quality of outputs in applications such as scanning electron micrographs, and other imaging systems.

The arrangement of the present invention has other features and advantages which will be apparent from or are set forth in more detail in the accompanying drawings, which are incorporated herein, and the following brief description, which together serve to explain certain principles of the present invention.

### BRIEF DESCRIPTION OF THE DRAWINGS

The present invention will be better understood fully from the detailed description that is given herein below with reference to the accompanying drawings of the preferred embodiments of the present invention, which, however, should not be deemed to be a limitation to the invention to the specific embodiments, but are for the purpose of explanation and understanding only.

FIG. 1A illustrates the signal flow and interaction of different components of a voltage driver according to present invention;

FIG. 1B illustrates the signal flow and interaction of different components of a current driver according to present invention;

FIG. 2 is the schematic illustration of microcontroller sheet with inputs from sheet ADC using SPI connection on sheet top level;

FIGS. 3A-3C illustrate the ADC sheet according to present invention;

FIGS. 4A-4I illustrate the microcontroller STM32 sheet according to present invention;

FIGS. 5A-5C illustrate the DAC sheet according to present invention;

FIGS. 6A-6F illustrate the sheet showing the PA99 amplifier module connected as an inverting amplifier;

FIG. 7 illustrates the sheet showing bandpass filter block;

FIGS. 8A-8C illustrate the buffer sheet with DC amplifier according to present invention; and

FIGS. 9A-9I illustrate the power and reference sheet according to present invention.

### DETAILED DESCRIPTION OF THE INVENTION

The embodiments herein and the various features and advantageous details thereof are explained with reference to the non-limiting embodiments and drawings in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The present invention discloses a system and method to generate ultra low noise voltage and current, by using feedback of noise via multiple ADC, and processing and feeding it to oversampling DAC to nullify the original, inherent noise produced by the electronic hardware components in the system.

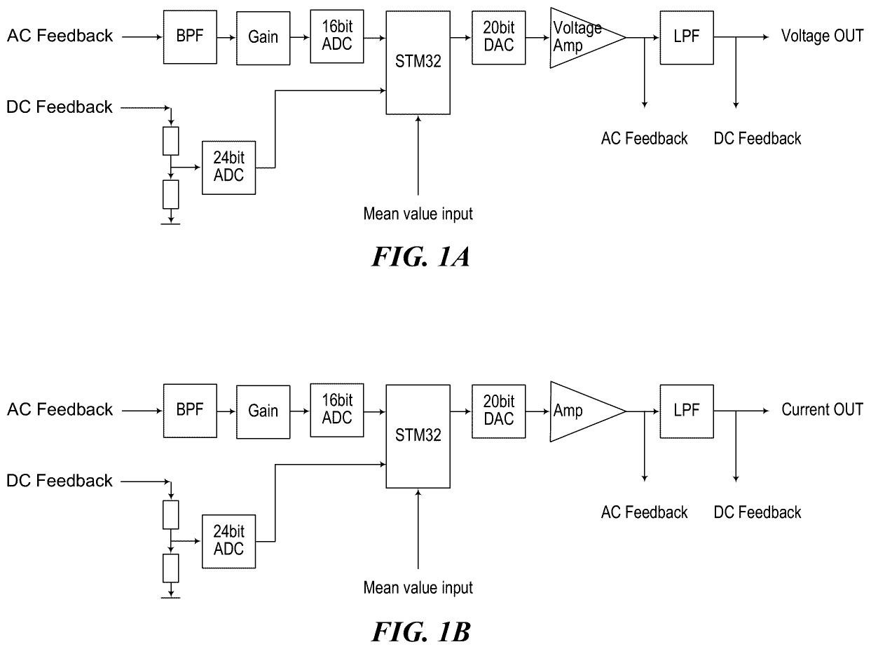

According to the present invention, referring to FIGS. 1A and 1B, the system to generate ultra low noise, high stability, high precision voltage or current source in applications involving electronic hardware components, comprises:
a. one or more Analog to Digital converters (ADCs) for high precision digital reading of DC and AC ripple values;
b. a microcontroller to process the ADC output readings and generate a waveform that when subtracted from the output to provide the steady, ripple-free output;
c. a digital to analog converter (DAC) to implement the subtraction generated from the microcontroller;
d. a high voltage amplifier for amplifying the ripple-free subtracted waveform output generated from the DAC and generating the output according to user command;
e. a very low frequency (VLF) noise bandpass filter (BPF) to detect the noise and filter out the significant frequency components to obtain the low frequency noise as output; and
f. power and reference section to provide necessary voltage levels and precision references for the proper functioning of the system,
   wherein the noise output from the filter is applied as negative feedback to eliminate maximum noise using extended precision oversampling DAC codes to nullify the original, inherent noise produced by the electronic hardware components containing applications.

To summarize, non-limiting main elements of the system are:
a. ADCs
b. STM32 Microcontroller
c. DAC
d. HV Amp
e. VLF noise bandpass filter
f. Buffer and
g. Power and Reference

ADCs are used to digitally read, with high precision, the DC and AC (ripple) values of the output. The STM32 controller process these readings and generates a waveform that when subtracted from the output will give the most steady, ripple-free output. The DAC is used for implementing this low voltage precision voltage output according to user input. HV amp is the main source of the output, which sets the main output according to the DAC output but adding its own inherent noise. VLF noise bandpass filter that filters out the significant frequency components (here, e.g., 0.1 Hz to 1000 Hz). Buffer strengthens the signals to make it usable to the next stage. There are 2 Buffers B1 and B2. The Power and reference section provides necessary voltage levels and precision references for the system to function properly.

In accordance with the present invention, applications containing electronic hardware components include scanning electron microscopes and other imaging systems.

In accordance with the present invention, the method for generating ultra low noise, high stability, high precision voltage or current source in applications involving electronic hardware components, comprising:
a. detecting noise using bandpass filter and measuring low frequency noise;
b. applying negative feedback of that noise to eliminate most of that noise using extended precision oversampling DAC codes to the existing codes used to set the output voltage and current; and
c. eliminating the low frequency noise and drift errors arising from the voltage reference source, or amplifier, or DAC LSB errors.

According to present invention, the system and method reduce the output noise of a voltage or current source, to a level far below to what is achieved by the state of art technologies. This technology basically scans the output in two ways, 1. DC feedback, 2. AC feedback. The DC feedback is used to set up and maintain the output, according to the command given to the system by the user, whereas the AC feedback is used to sample the ripple, and by using a Microcontroller and Firmware combination, process the ripple, and nullify it at the output, by subtracting from the output. This subtraction is achieved by an over-sampled DAC that provides 24-bit effective resolution at a lower sample rate.

In accordance with one embodiment of the present invention, bandpass filter, amplifier, first ADC (e.g. 16 bits) are used for the low frequency and flicker noise detection; Precision attenuation of output voltage (to match high voltage output signal to low voltage DC ADC, in case of voltage generator apparatus), OR Precision amplifier of detected current signal (in case of current generator apparatus); which then feeds a 24 bits DC ADC which is used for drift detection, A fast digital signal processor/microcontroller is used for voltage or current calculations, error detection, digital filtering, error feedback calculator, the addition of set point value for mean output, addition of drift error as feedback; 20 bits DAC is used for oversampling conversion to higher resolution and for the output stage high precision voltage or current amplifier.

In accordance with present invention, the dual feedback loop is important to eliminate both the static or DC error (1^{st} feedback signal) as well as the low frequency or flicker type noise (2^{nd} feedback signal).

Hereinafter, high precision high voltage driver theory of operation is described in conjunction with schematic diagrams.

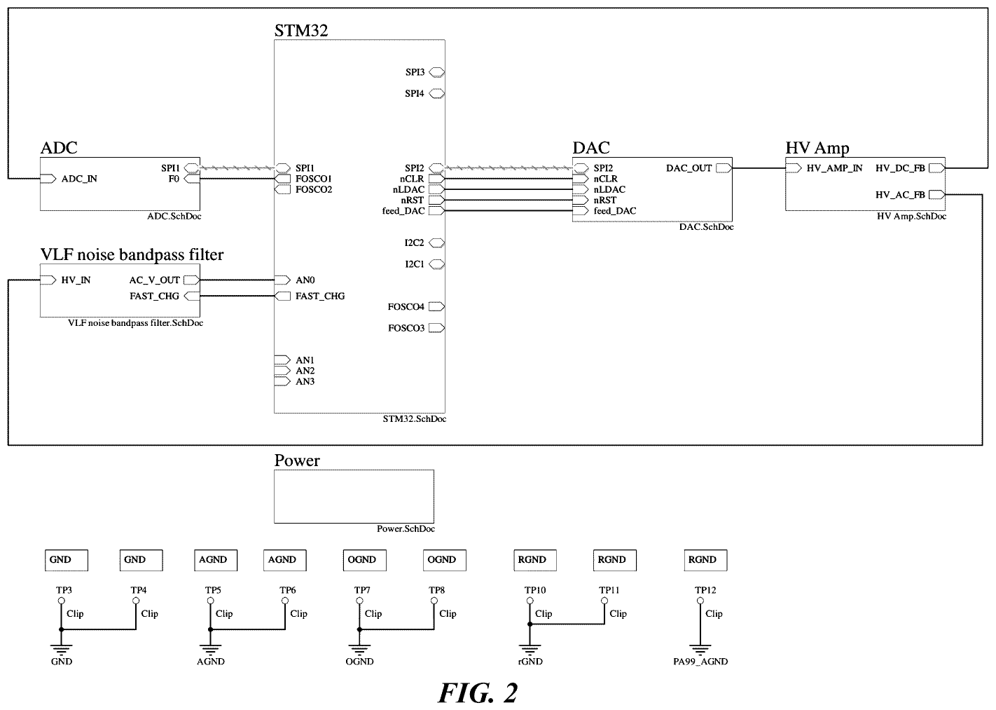

The schematics represented in FIGS. 2 to 9I describe a voltage source with the Ultra-Low Noise technology implemented. Implementation of this technology to a Current source is very similar to this, and so omitted here, to avoid repetitions.

a. Top Level

On sheet Top level as shown in FIG. 2, there is a microcontroller sheet STM32 with inputs from sheet ADC using SPI connection; outputs to a DAC using second SPI connection with additional control pins; the DAC outputs feed a HV (high voltage) Amp(lifier) sheet which has DC feedback return to the ADC and AC feedback return to the VLF (very low frequency) noise bandpass filter sheet; the VLF filter feeds the AN0 analogue input to the STM32; finally the power sheet supplies the DC power rails to all the low voltage circuitry.

b. ADC

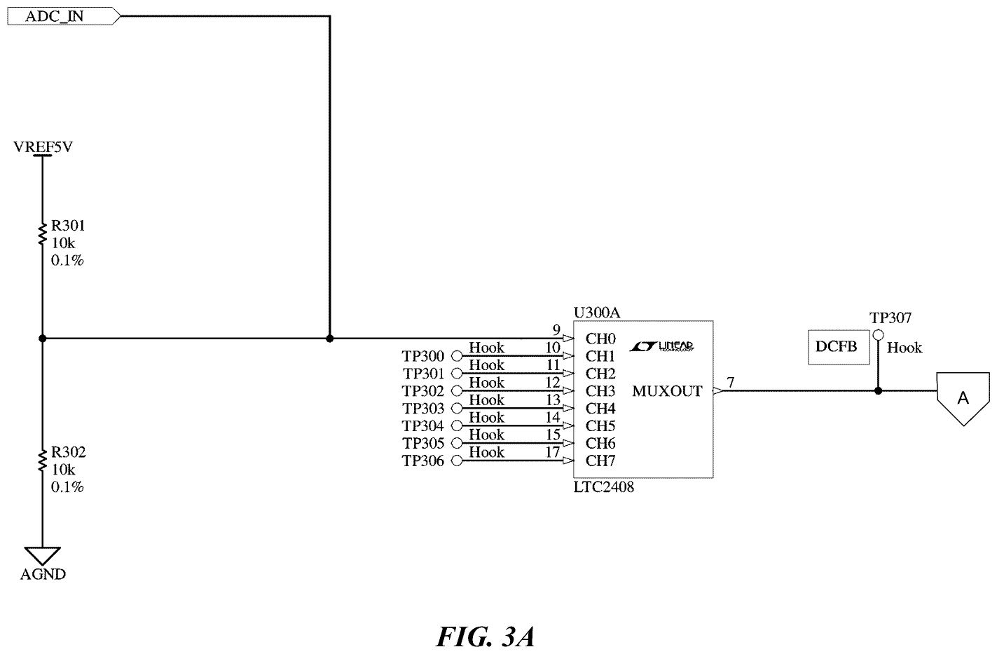

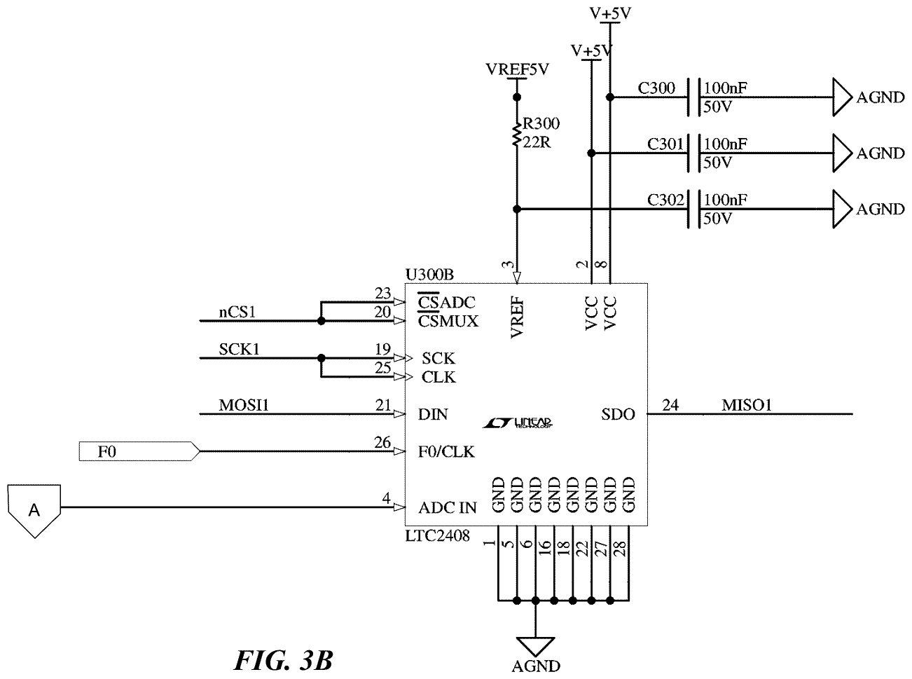

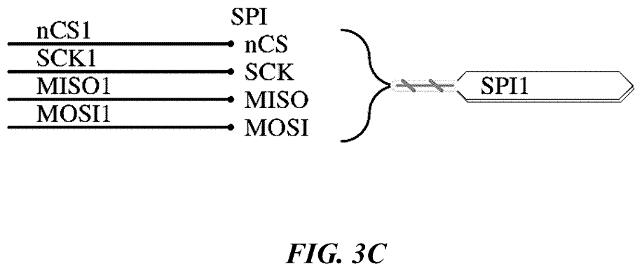

On ADC sheet as shown in FIGS. 3A-3C, U300 is a 24-bit ADC (LTC2408) with a multiplexor which takes ADC IN signal and biases this to be within the 0 to 5V reference range of the ADC. F0 signal input allows the ADC to run synchronously to the clock generated by the STM32. The signal harness SPI1 is driven by the STM32 to read the ADC as required. R303 provides a return GND signal path for the SPI signals to minimize the disturbance to the sensitive circuitry. The most important criteria for choosing the LTC2408 are 24-bit nominal, low INL (4 ppm), and reasonable conversion time of 160 ms (6.25 Hz with excellent 50 Hz rejection).

c. STM32

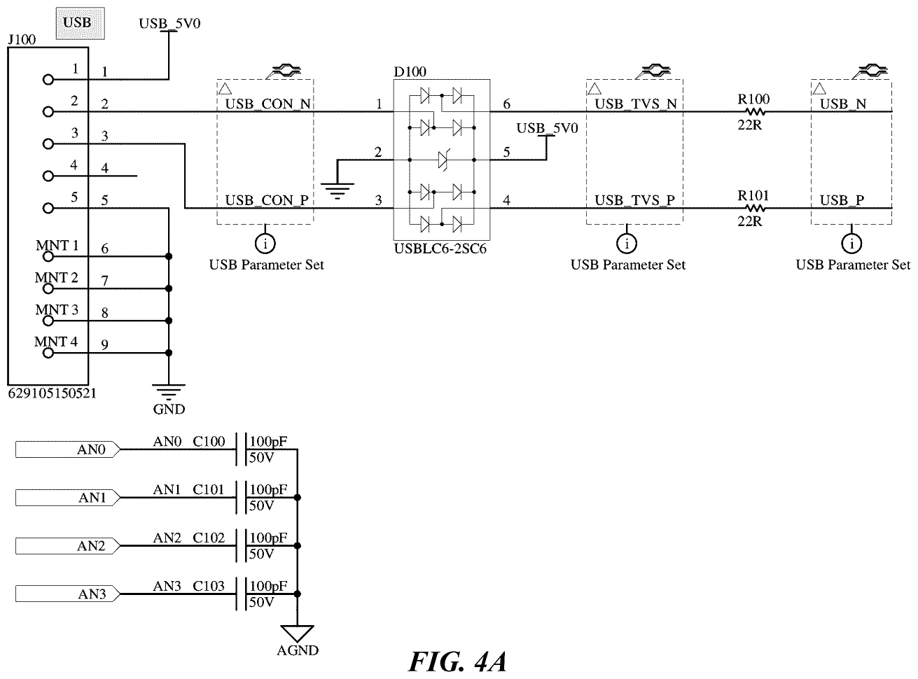

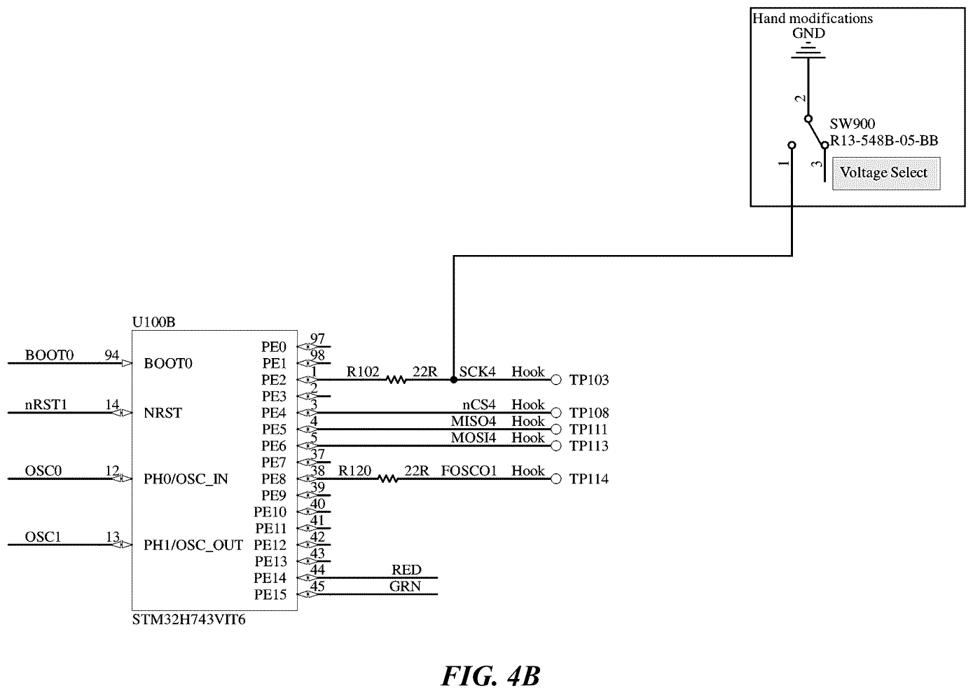

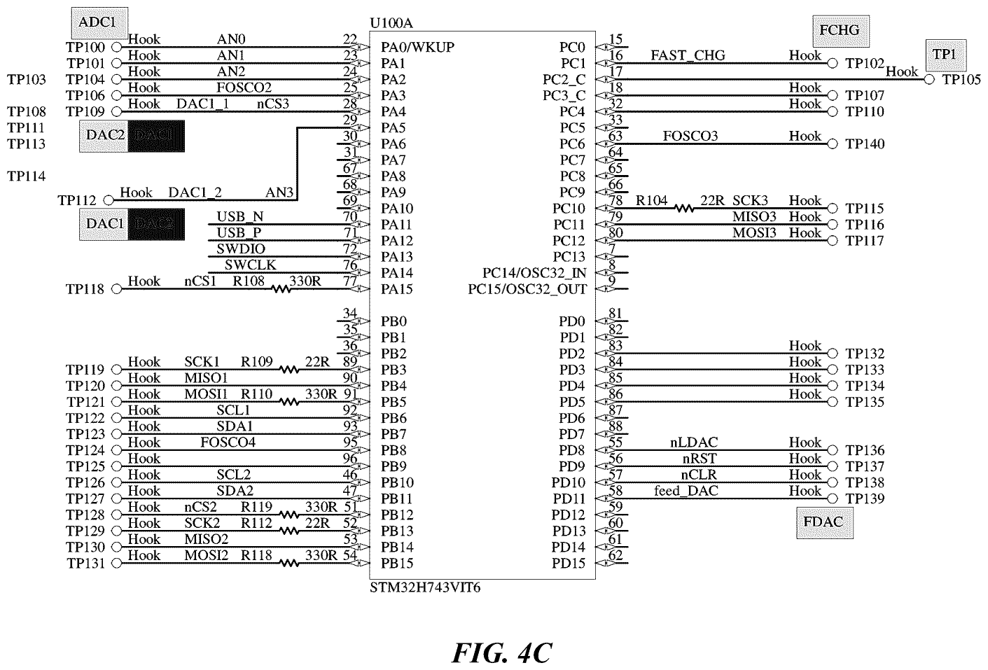

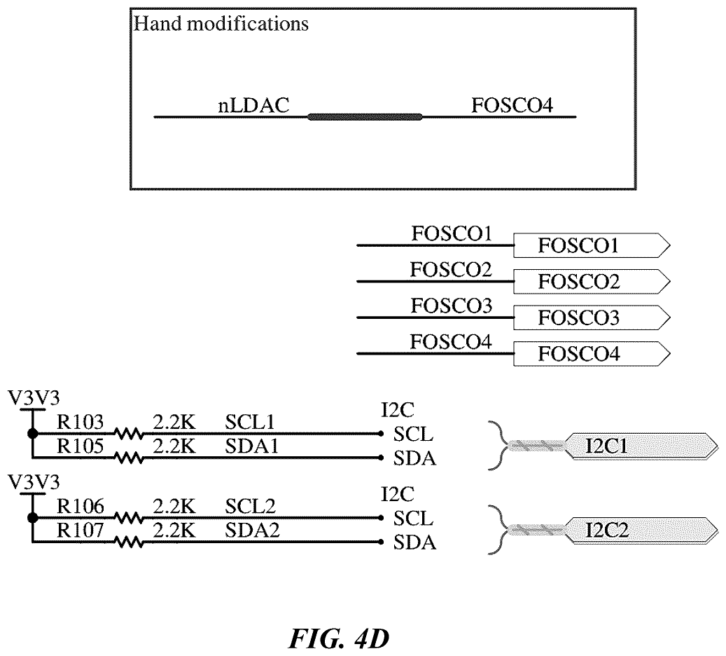

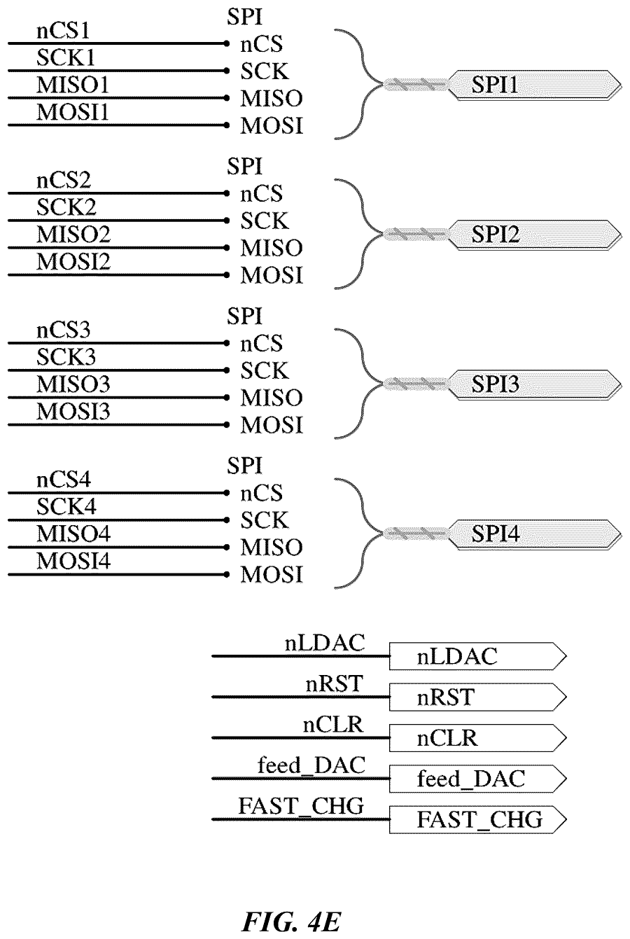

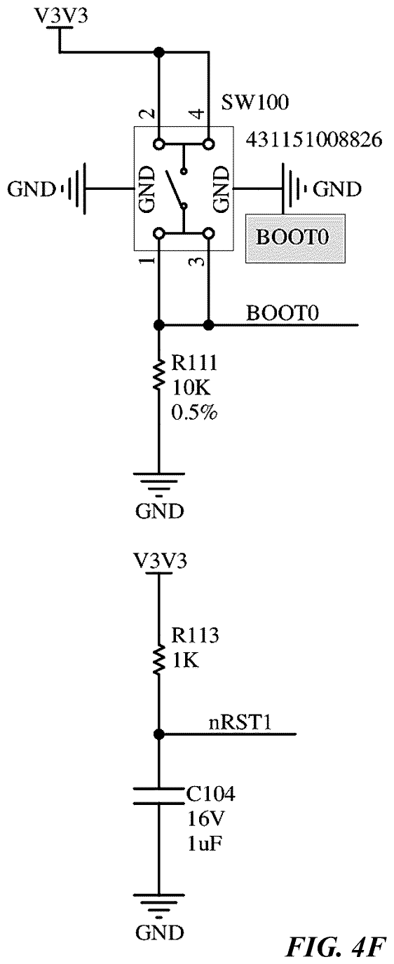

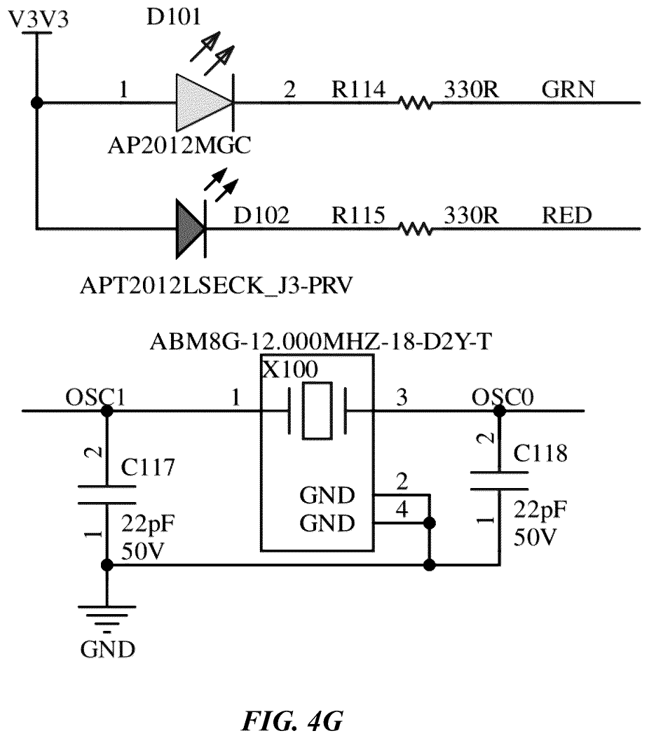

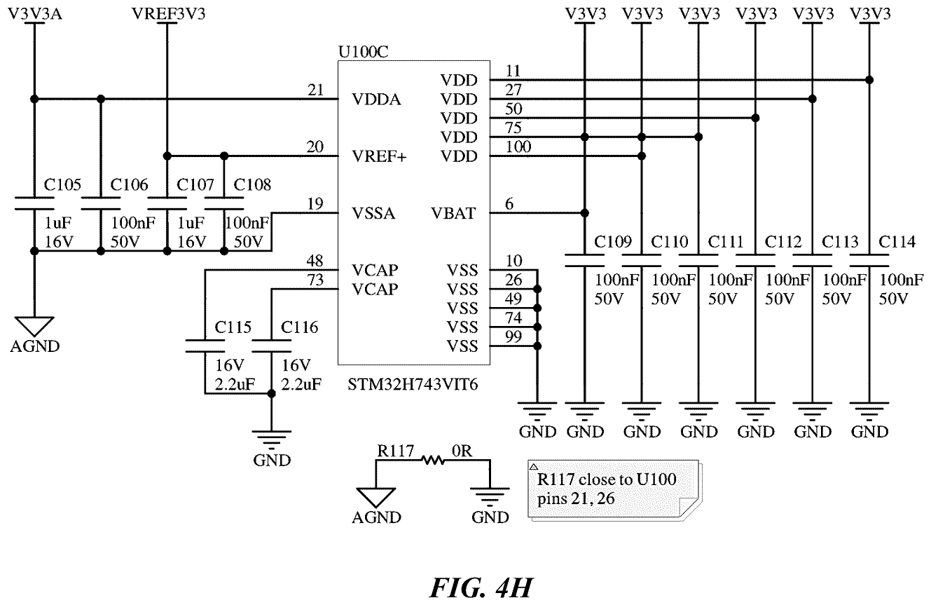

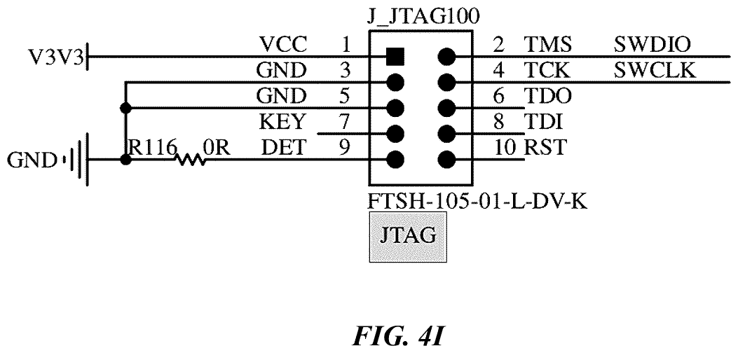

On STM32 sheet as shown in FIGS. 4A-4I, U100 is split to show different sections. U100A shows Boot, Clock, Reset, debug LED and SPI4 connections. U100C shows the power supply and decoupling section with separate analogue and digital grounds. J100 provides a USB control port for external control information to be provided and status to be read. J_JTAG100 connector provides programming capability using an ST-LINK programming device. U100A shows the connections to various peripherals including SPI1 to SP3 busses, analogue inputs AN0 to AN2, DAC outputs for monitoring the digitally filtered signals measured by the STM32, etc. The criteria to choose the STM32H743 was the 16 bit ADC, floating point processor, and familiarity with this high speed processor from previous projects.

d. DAC

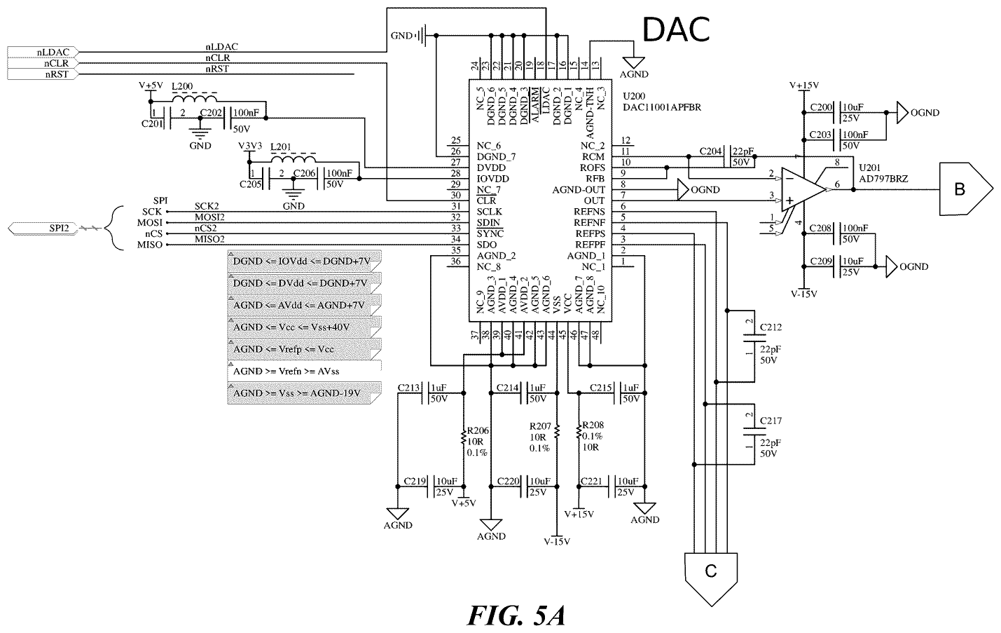

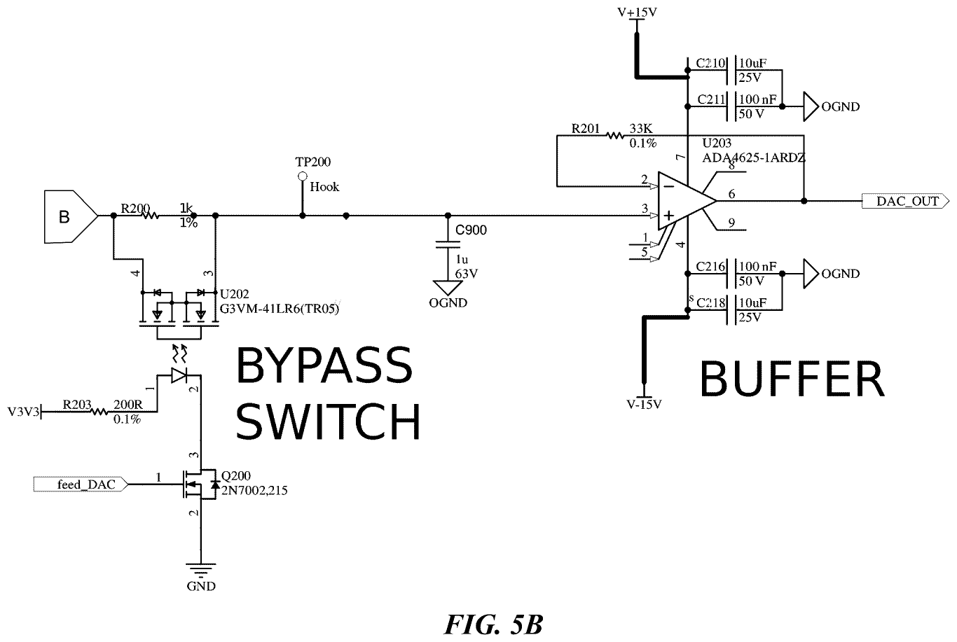

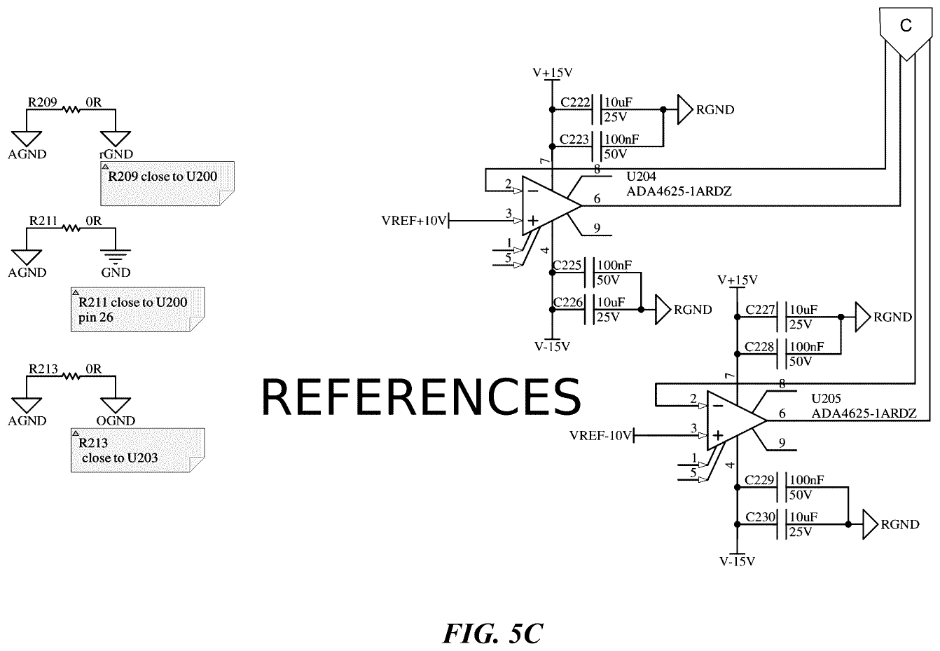

On DAC sheet as shown in FIGS. 5A-5C, the high precision 20 bit DAC (DAC11001) is shown which receives data on the SPI2 bus. The DAC can be configured to only update the output on the rising edge of the signal nLDAC. Signal nCLR, when low, forces the DAC output to the value at the REFNS pin, and to the normal data signal level when high. U204 and U205 provide buffered +10V and −10V reference levels via sense and force pins. U201 provides a buffered output of the DAC signal. R200/R210 with C207 provide a programmable 1st order filter which is buffered by U203 to create the signal DAC_OUT. The most important criteria for choosing the DAC11001A are at least 20 bit, low DNL (monotonic), low INL, and low glitch at any code. The fast settling time of lus is excellent too. This high speed allows oversampling to increase the effective resolution from 20 to more than 24 bit equivalent.

e. HV Amp

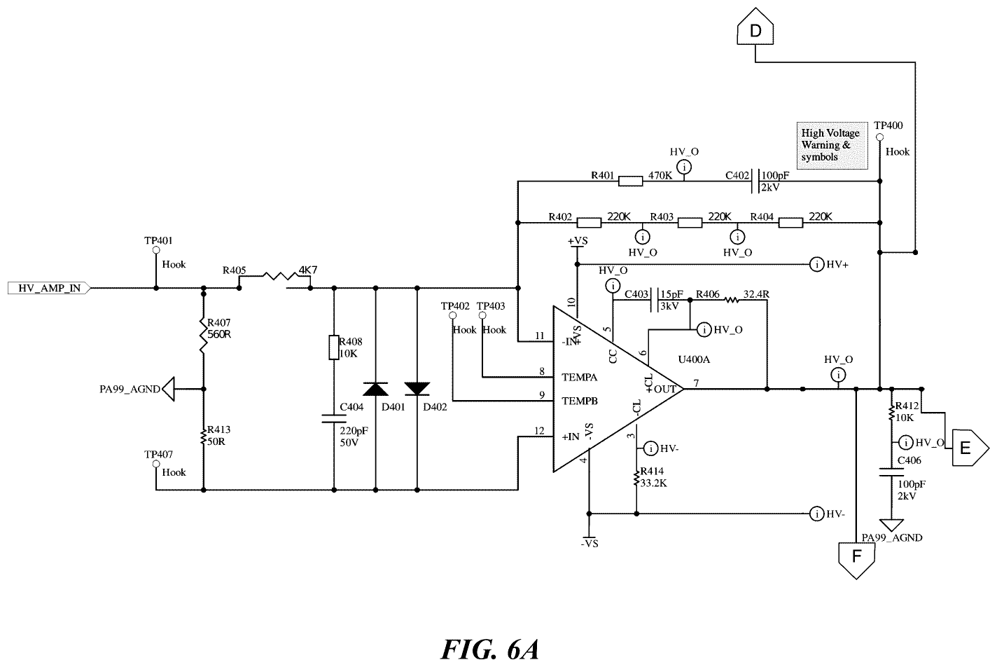

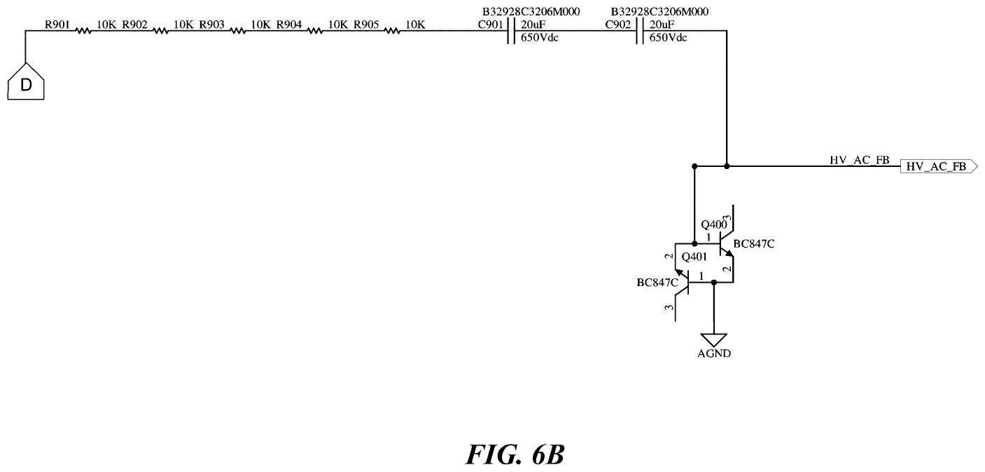

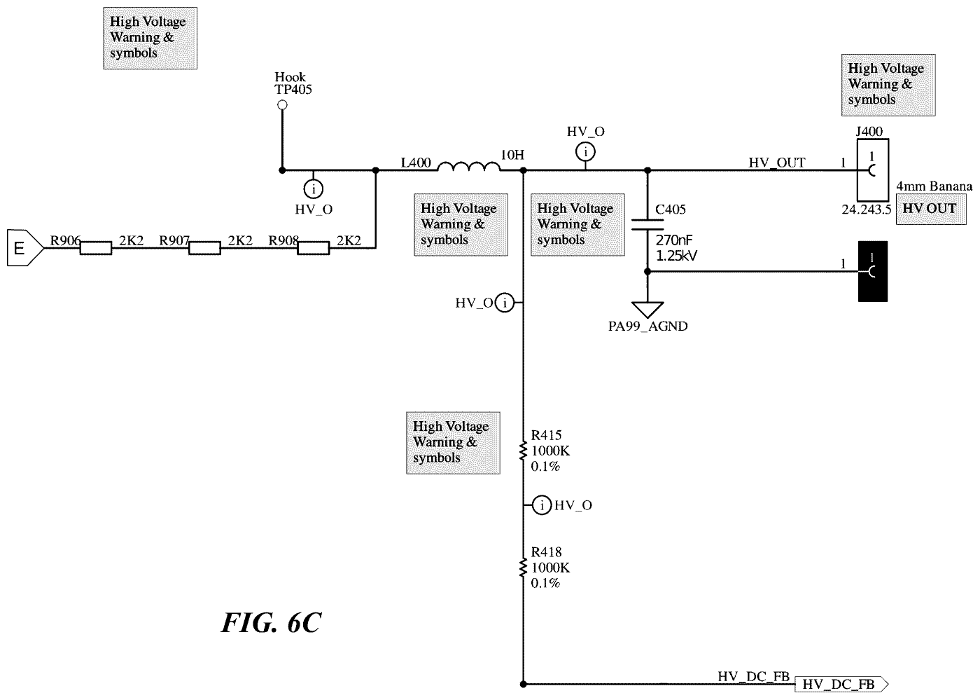

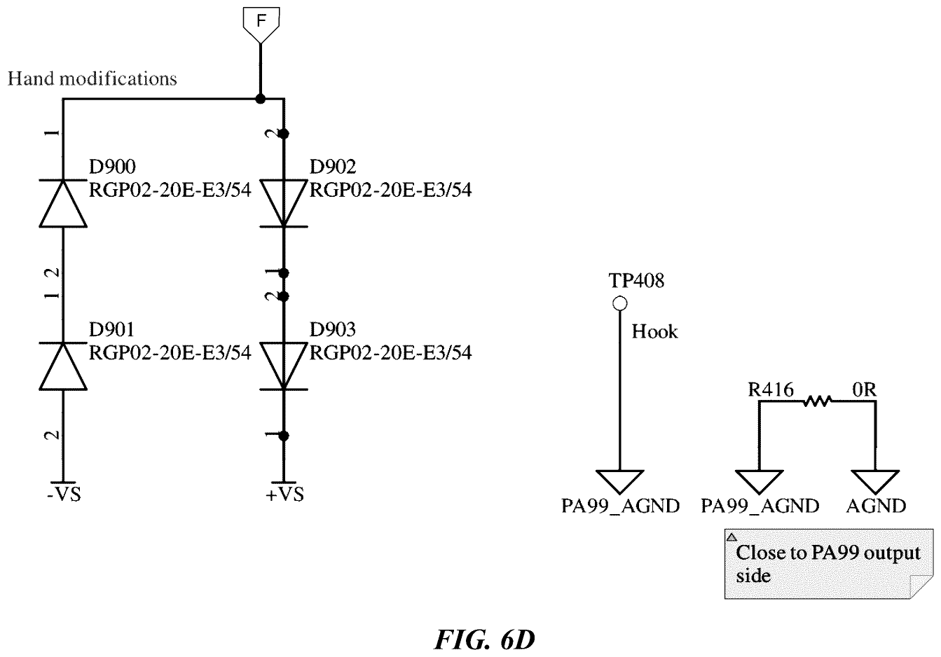

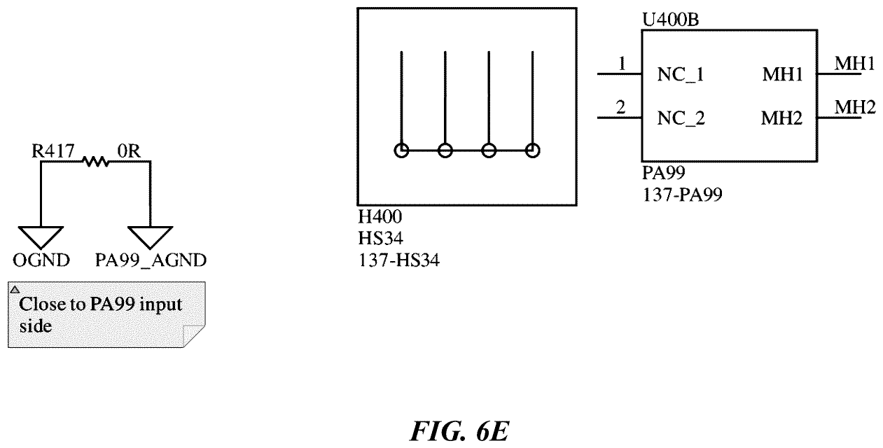

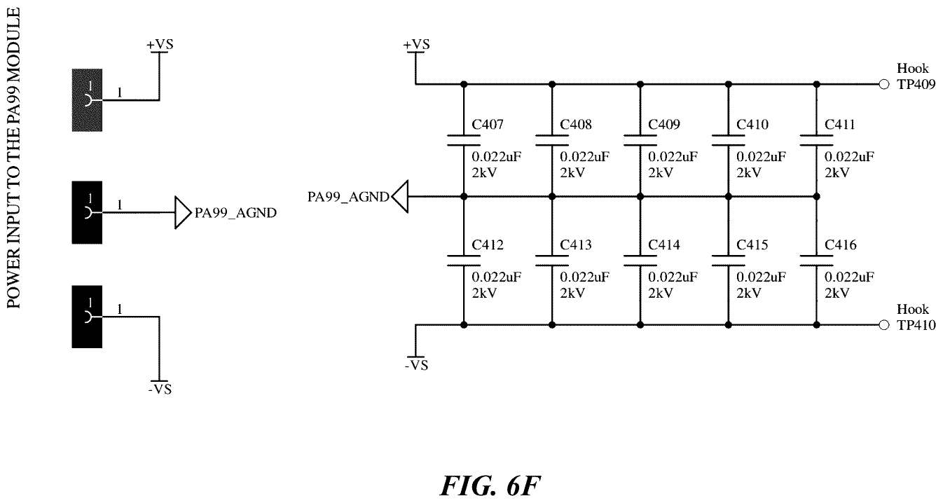

This sheet shows the PA99 amplifier module connected as an inverting amplifier of gain 99 as shown in FIGS. 6A-6F increasing the voltage applied at the HV_AMP_IN input to the HV_OUT signal on J400. Refer to the PA99 datasheet for further details of the components around the PA99 on this page. R409, R410, L400, C405 provide a low pass filtered output of the amplifier to drive the deflector plates. R411, R4100, C400 C401 provide a high pass filtered output clamped to under 1V from ground by Q400, Q401. R415, R418 provide a DC feedback signal clamped to around +/−5V by Q402, Q403 and D404, D405. Together with the bias resistor circuitry of the ADC sheet, the HV_DC_FB signal is normally between 0 and +5V. The criteria for choosing this amplifier was sufficient gain bandwidth with high voltage drive capability without requiring specialist high voltage design experience. The low inherent noise of <10 mV LF noise at around 1 kV output was very useful.

f. VLF Noise Bandpass Filter

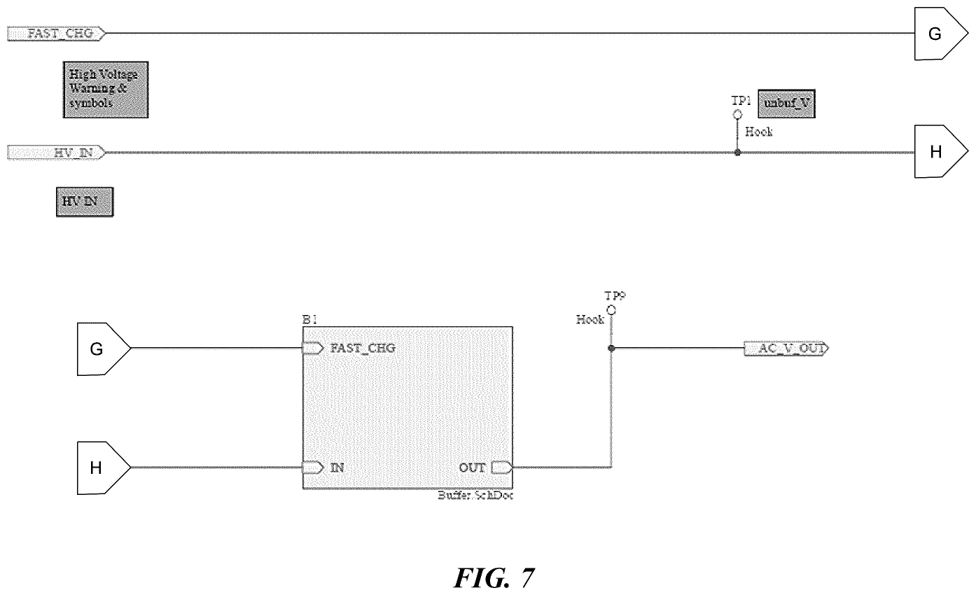

This sheet shows two filter blocks of the Buffer sheet as shown in FIG. 7. B1 is used to create an amplified AC signal at the AC_V_OUT port for AC feedback to the STM32 at a nominal 1.65V dc bias level. B2 is used to provide an amplified monitor signal for external detection/measurement at J1.

g. Buffer

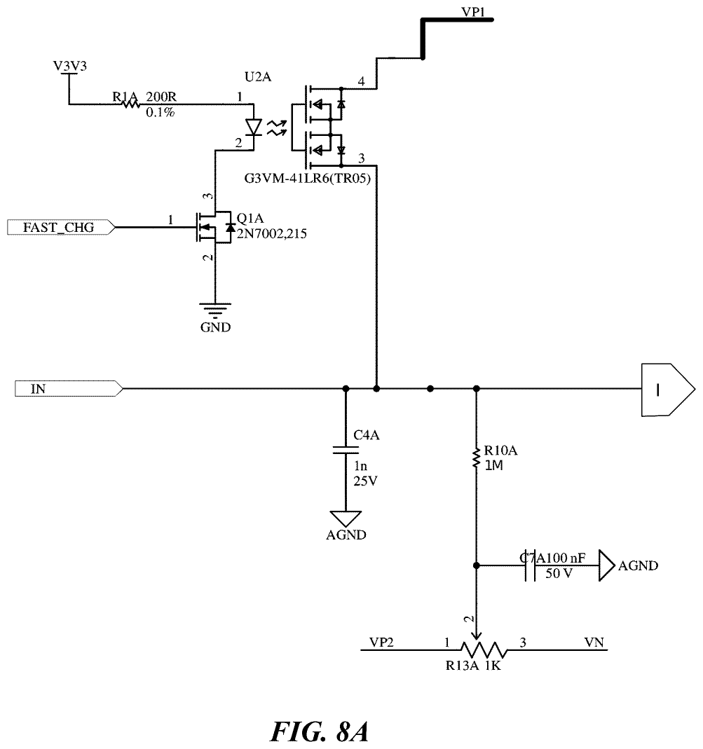

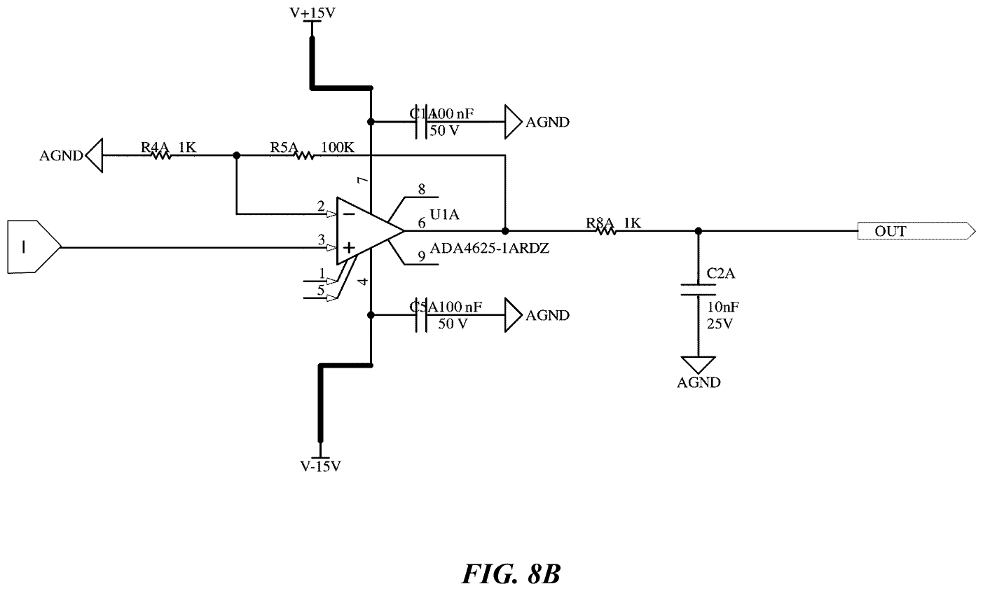

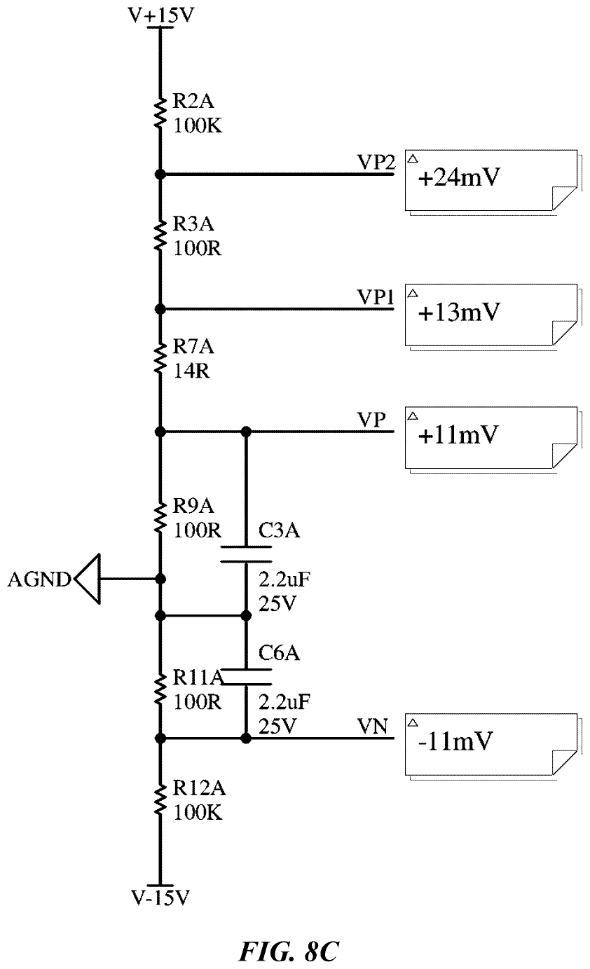

As shown in FIGS. 8A-8C, this sheet shows a DC amplifier of gain 100 with a low pass filter of the input impedance (approx. 20K) and C4 and also R8, C2 before being fed to the OUT port. The input signal has a high pass filter from ed by the input capacitance (around 10 uF) and R10. Thus, the signal at OUT is a bandpass with first order high pass at around 0.1 Hz and low pass at 1 kHz. The resistor chain R1 to R12 provides DC bias levels at various voltages to set the DC output of U1 using R13. When signal FAST_CHG is high the relay U2 allows the coupling capacitors connected to the IN input to be quickly charges/discharged to the VP1 level, so that the high pass frequency can be temporarily increased to reduce the settling time of this measurement circuit.

h. Power and Reference

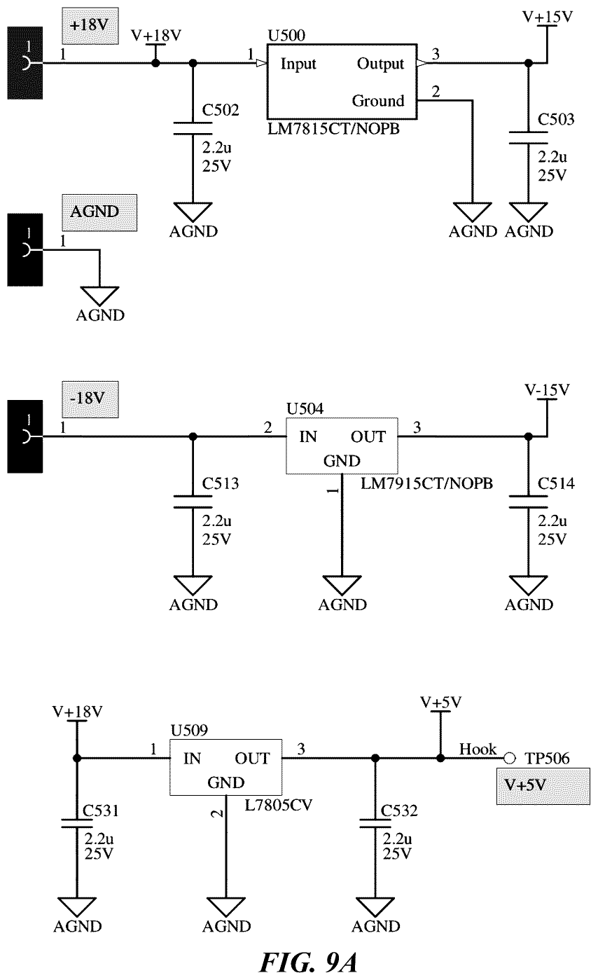

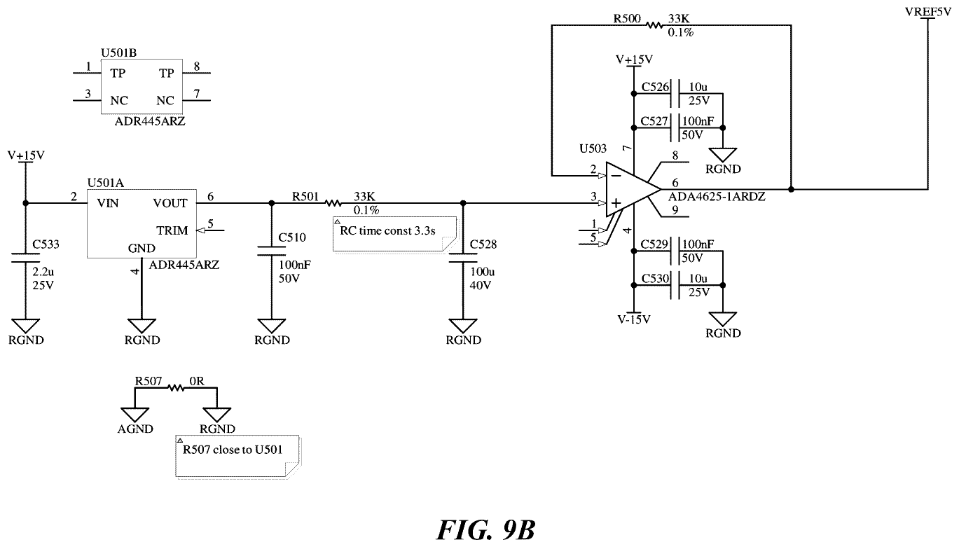

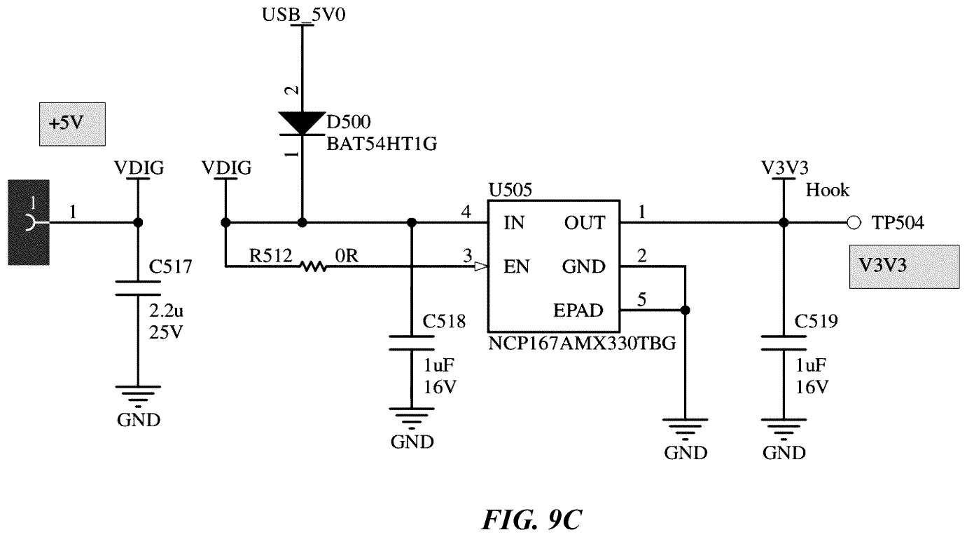

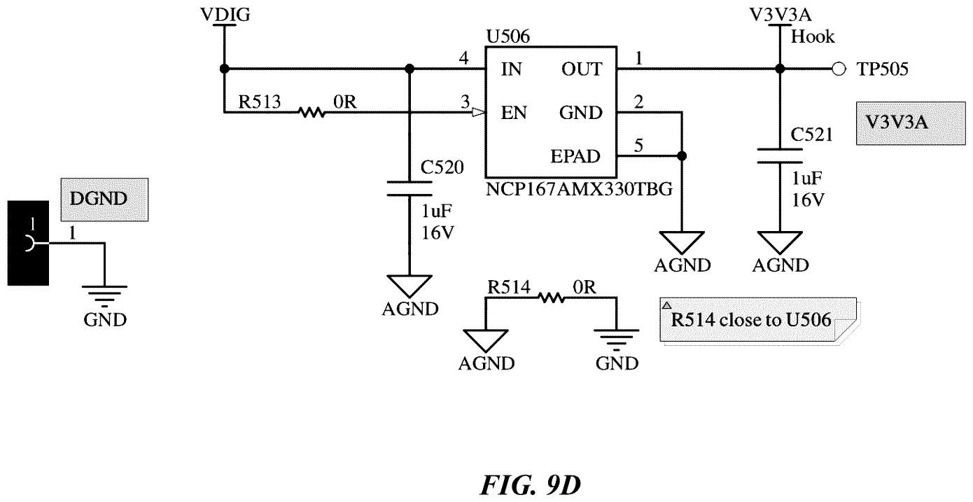

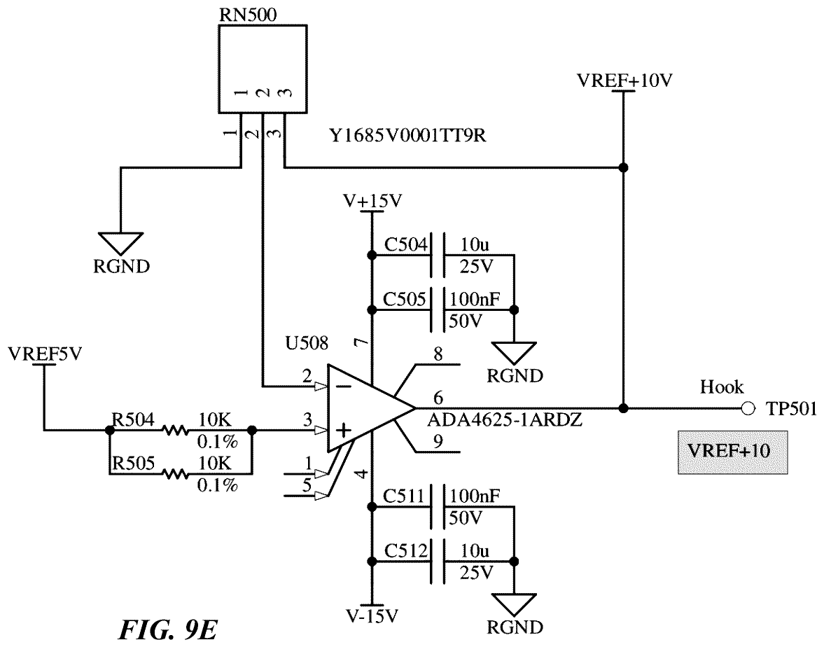

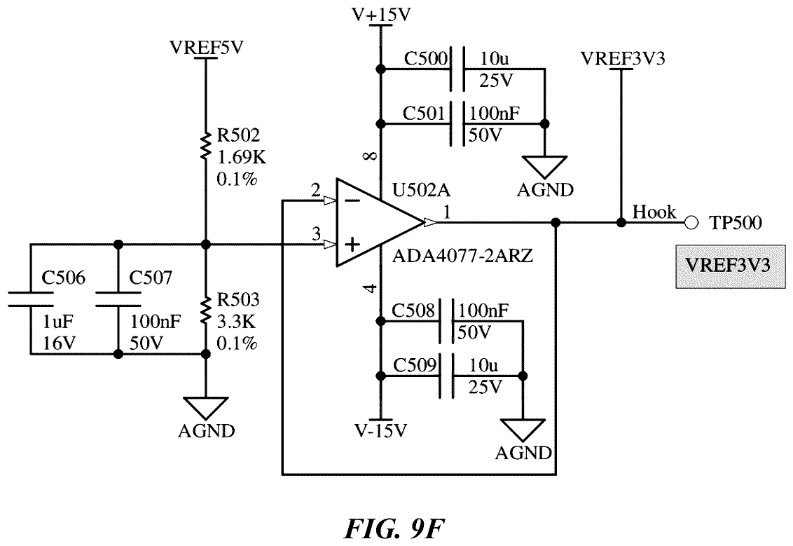

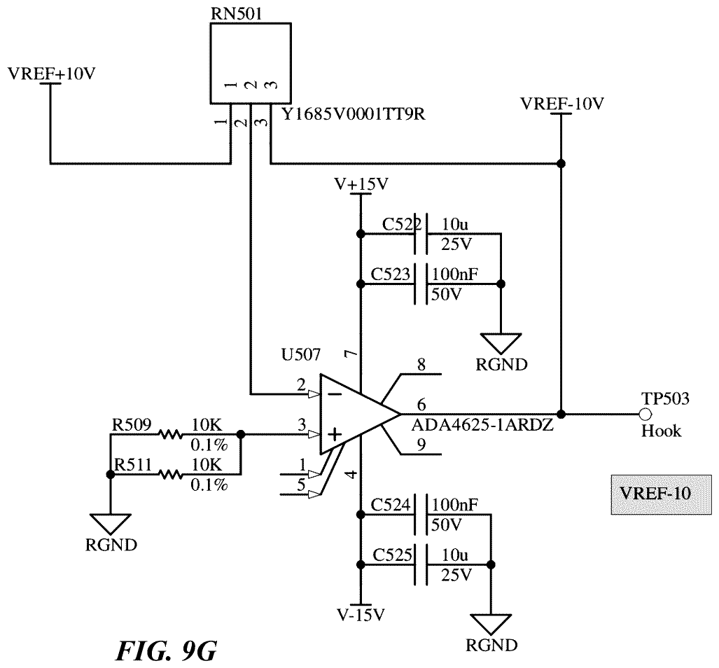

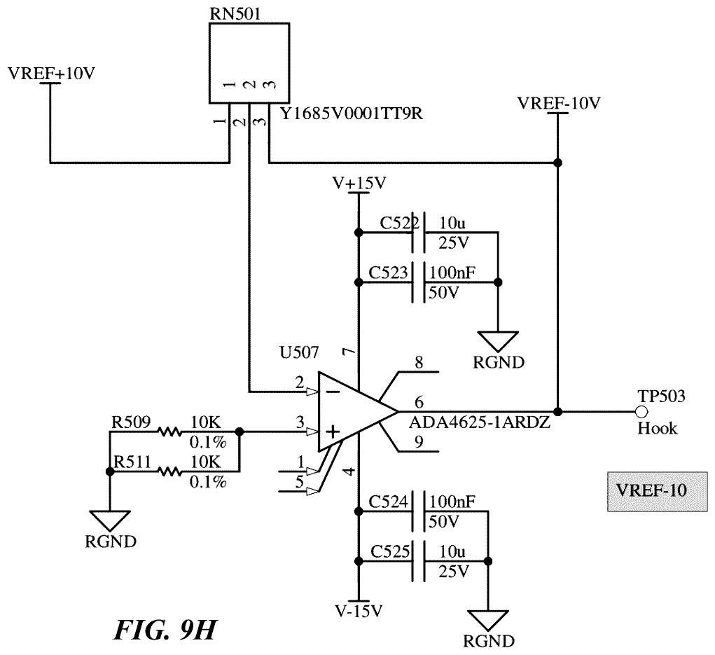

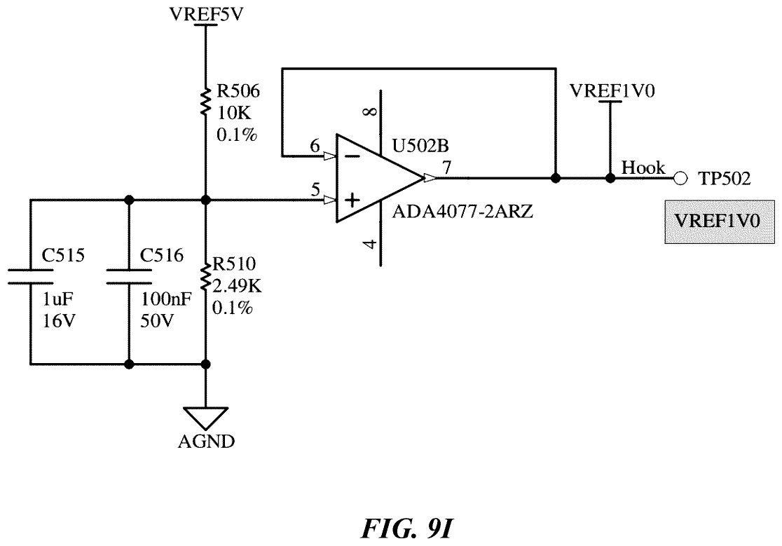

The Power sheet as in FIGS. 9A-9I shows the low voltage supplies which take unregulated +/18V for analogue rails (U500, U504) and +5V for the STM32 supplies (U505, U506). An additional +5V for the analogue section is derived from the +18V (U509).

U501 provides a +5V reference which is filtered to reduce even LF noise using R501, C528. This filtered voltage is buffered by U503 to give VREF+10V and then inverted by U507 to provide VREF−10V. An important criteria for U503 is low input bias current as well as low noise, particularly LF noise. U502 provides a stable ref for the STM32 ADC, although this not strictly necessary.

Hereinafter, the PCB and software details of the present invention is described below:

### Software Details

i. DC Feedback Algorithm

The purpose of this is to read the LTC2408 ADC, calculate a long term average of the DC output level of the voltage at J400 output, then to calculate the correction to send to the DAC and amplifier stage to keep the output constant. The reference amplifiers may drift in gain/offset as well as the PA99 amplifier but in effect, as long as such drifts are compensated for, it does not matter where the error comes from.

j. AC Feedback Algorithm

The purpose of this is to read the internal ADC at a high rate, calculate a short term average of the AC deviation of the voltage at J400 output, then to calculate the AC correction signal to keep the output constant. Regardless of where the AC error comes from (reference, reference amplifier, HV amplifier) the LF or shot noise error can be very significantly reduced.

k. Oversampling Dither

This is the noise that is added to the DAC digital input to linearize the differential/integral LSB errors in the DAC construction. This noise, which is many times larger than one LSB is filtered out by the low pass filter after the HV amplifier (R409, L400, C405).

Advantageously, the system and method of present invention reduces noise and drift errors in a generated voltage or current source and improve the quality of outputs in applications such as scanning electron micrographs, and other imaging systems.

The present invention when applied with the described hardware and software, will reduce noise and drift errors in a generated voltage or current source. Hence, the present invention produces voltage and current that is cleaner (low level of noise and drift) than that is possible by the present state-of-art technologies.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope of the invention as claimed.

We claim:

1. A system to generate ultra low noise, high stability, high precision voltage or current source of electronic hardware components, comprising:
a. two or more Analog to Digital converters (ADCs) for high precision digital reading of DC and AC ripple values;
b. a microcontroller to process the ADC output readings and generate a waveform that when subtracted from the output to provide the steady, ripple-free output;
c. a digital to analog converter (DAC) to implement the low voltage precision voltage output according to user input;
d. a high voltage amplifier for amplifying the ripple-free subtracted waveform output generated from the DAC and generating the output according to user command;
e. a very low frequency (VLF) noise bandpass filter (BPF) to detect the noise and filter out the significant frequency components to obtain the low frequency noise as output; and
f. a power and reference section to provide necessary voltage levels and precision references for proper functioning of system,
wherein the noise output from the filter is applied as a negative feedback to eliminate maximum noise using extended precision oversampling DAC codes to nullify the original, inherent noise produced by the electronic hardware components containing applications.

2. The system as claimed in claim 1, wherein the system comprises one or more buffers to strengthen the signal for the next stage.

3. The system as claimed in claim 1, wherein the electronic hardware components include imaging system applications.

4. The system as claimed in claim 3, wherein the imaging system applications include scanning electro microscopes.

5. A method for generating ultra low noise, high stability, high precision voltage or current source in electronic hardware components, comprising:
a. detecting noise using bandpass filter and measuring low frequency noise;
b. applying negative feedback of that noise to eliminate most of that noise using extended precision oversampling DAC codes to the existing codes used to set the output voltage and current; and
c. eliminating the low frequency noise and drift errors arising from the voltage reference source, or amplifier, or DAC LSB (Least Significant Bit) errors.
